(19) United States
(12) Patent Application Publication
(10) Pub. No.: US 2007/0123050 A1
(43) Pub. Date: May 31, 2007

(54) Etch process used during the manufacture of a semiconductor device and systems including the semiconductor device

(75) Inventors: Baosuo Zhou, Boise, ID (US); Mirzafer K. Abatchev, Boise, ID (US); Krupakar M. Subramanian, Boise, ID (US)

Correspondence Address: MICRON TECHNOLOGY, INC., 8000 FEDERAL WAY, MAIL STOP 525, BOISE, ID, 83707-0006, US

(73) Assignee: Micron Technology, Inc.

(21) Appl. No.: 11/272,980

(22) Filed: Nov. 14, 2005

(51) Int. Cl. C23F 1/00; H01L 29/04; H01L 21/461; B44C 1/22; H01L 31/036

(52) U.S. Cl. 438/706; 216/41; 216/78; 257/49

(57) ABSTRACT

A carbon or carbon-containing underlayer, which is used as a mask, is patterned using a process comprising, in one specific embodiment, boron trichloride and oxygen under specified processing conditions to etch the underlayer. The underlayer is then used as a mask to etch a layer below the underlayer, such as a semiconductor wafer or a layer formed as part of a semiconductor wafer substrate assembly. Various processing conditions are described, as is the formation of various features using embodiments of the inventive process.

### FIELD OF THE INVENTION

This invention relates to the field of semiconductor manufacture and, more particularly, to an etch used to remove carbon and carbon-containing materials selective to a hard mask.

### BACKGROUND OF THE INVENTION

During the formation of a semiconductor device, many features such as word lines, digit lines, contacts, and other features are commonly formed over a semiconductor wafer substrate assembly, as are etched openings in a semiconductor wafer itself. Using prior digit line manufacturing methods as an example, digit lines have typically been formed by providing one or more conductive layers, depositing a photoresist layer over the conductive layer or layers, patterning a photoresist layer using an optical lithographic process, then etching the conductive layer using the photoresist layer as a mask. During the etch of the conductive layer, the photoresist layer is also eroded away; thus, the photoresist layer must be sufficiently thick so that at least a portion of the photoresist layer remains at the end of the etch of the conductive layer. However, with decreasing line widths, the required thickness of the photoresist relative to the line width becomes excessive, and the photoresist becomes increasingly susceptible to a phenomenon known as “toppling” due to structural instability of the photoresist structure after patterning.

As a result, hard masks have been used to reduce the required thickness of the photoresist. The hard mask is a material which etches at a slower rate than the overlying photoresist during the etch of the conductive layer. Various hard mask materials include silicon, silicon nitride, silicon dioxide, a dielectric antireflective coating (DARC), or other silicon-containing materials including polymers. When the entire thickness of the photoresist layer is removed, the hard mask remains to mask the conductive layer, and the etch may continue after the resist has been completely etched away.

One problem with hard materials is that, when exposed to an etchant, they tend to form polymers over exposed surfaces of the semiconductor wafer substrate assembly. These polymers may be difficult to remove, especially from the bottom of openings formed during the etch. Thus photoresist and a hard mask may be used in combination with an underlayer to minimize the thickness of the hard mask. A carbon layer or a carbon-containing layer, for example transparent carbon or another amorphous carbon layer, may function as an underlayer. Formation and use of carbon layers are described in U.S. Pat. No. 6,939,794 and US Pub. No. 2005/0059262 A1, both by Yin, et al., which are assigned to Micron Technology, Inc. and incorporated herein as if set forth in their entirety. With an underlayer, the photoresist pattern is transferred to a thin hard mask, then the hard mask pattern is transferred to the underlayer which is formed on the conductive layer prior to hard mask formation. The hard mask is commonly used because it may not be possible to form the photoresist to a sufficient thickness to insure that a minimum thickness remains subsequent to the completion of the underlayer etch.

Transferring the photoresist pattern to the hard mask, then to the underlayer, and eventually to the conductive layer with maximum pattern integrity is a significant processing concern. Lateral etching of the hard mask or underlayer degrades the pattern transferred to the conductive layer. Similarly, if a polymer forms during the etch of the hard mask and/or the underlayer, the opening in the underlayer may have a decreased width, which is then transferred to the conductive layer. This may result in increased feature resistance, a physical weakening of the structure, an electrical open, or misalignment between features, depending on the particular feature being formed. Transparent carbon and other carbon-containing layers are desirable as an underlayer because they are readily etched with an anisotropic etch to result in vertical or near-vertical sidewalls, which aids in accurate pattern transfer, and these materials as underlayers may be removed relatively easily after etching the conductive layer.

Etching the underlayer selective to the hard mask and to the semiconductor wafer substrate assembly is one goal of semiconductor processing engineers. An etch for a carbon or carbon-containing underlayer having good selectivity to a hard mask and to one or more layers of the semiconductor wafer substrate assembly would result in a uniform pattern transfer from a photoresist layer to an underlayer, and thus to a layer beneath the underlayer, and would be desirable.

### SUMMARY OF THE INVENTION

The present invention provides an etch which removes carbon and carbon-containing compounds used as an underlayer at a high etch rate relative to a substantially carbon-free layer, or to a layer comprising carbon and silicon, such as a hard mask. One particular etch comprises the use of boron trichloride (BCl₃) and oxygen (O₂) under specified conditions. The underlayer may then be used as a mask to etch a layer below the underlayer.

Advantages will become apparent to those skilled in the art from the following detailed description read in conjunction with the appended claims and the drawings attached hereto.

### BRIEF DESCRIPTION OF THE DRAWINGS

FIGS. 1-5 are cross sections depicting in-process structures for an exemplary method comprising the use of an etch;

FIG. 6 is an isometric depiction of various components which may be manufactured using devices formed with an embodiment of the present invention; and

FIG. 7 is a block diagram of an exemplary use of the invention to form part of a memory device having a storage transistor array.

It should be emphasized that the drawings herein may not be to exact scale and are schematic representations. The drawings are not intended to portray the specific parameters, materials, particular uses, or the structural details of the invention, which may be determined by one of skill in the art by examination of the information herein.

### DETAILED DESCRIPTION OF THE ILLUSTRATED EMBODIMENTS

The term “wafer” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” in the following description, previous process acts may have been utilized to form regions or junctions in or over the base semiconductor structure or foundation. Additionally, when reference is made to a “substrate assembly” in the following description, the substrate assembly may include a wafer with layers including dielectrics and conductors, and features such as transistors, formed thereover, depending on the particular stage of processing. In addition, the semiconductor need not be silicon-based, but may be based on silicon-germanium, silicon-on-insulator, silicon-on-sapphire, germanium, or gallium arsenide, among others. Further, in the discussion and claims herein, the term “on” used with respect to two layers, one “on” the other, means at least some contact between the layers, while “over” means the layers are in close proximity, but possibly with one or more additional intervening layers such that contact is possible but not required. Neither “on” nor “over” implies any directionality as used herein. The term “about” indicates that the value listed may be somewhat altered, as long as the alteration does not result in an excessive negative impact to the process or structure. A “spacer” indicates a layer, typically dielectric, formed as a conformal layer over uneven topography then anisotropically etched to remove horizontal portions of the layer and leaving vertical portions of the layer.

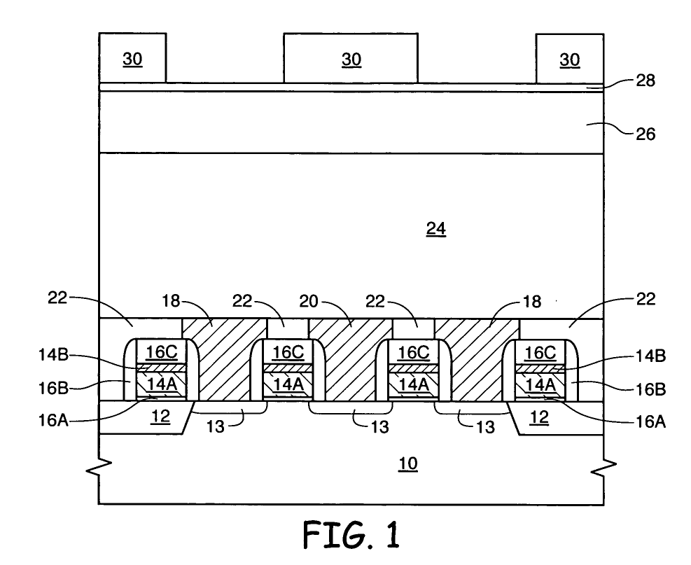

FIGS. 1-5 depict one example use of the invention to form a capacitor bottom plate during the formation of a semiconductor memory device such as a dynamic random access memory (DRAM). FIG. 1 depicts a semiconductor wafer substrate assembly comprising a semiconductor wafer 10, shallow trench isolation (STI) field oxide 12, doped wafer areas 13, transistor control gates for example comprising a tungsten nitride gate 14A and tungsten conductive enhancement layer 14B (or polysilicon gate and silicide), and surrounding dielectric typically comprising gate oxide 16A, silicon nitride or aluminum oxide (Al₂O₃) spacers 16B, and capping layer 16C, for example tetraethyl orthosilicate (TEOS) or silicon nitride. FIG. 1 further depicts polysilicon contact pads including pads 18 to which container capacitors will be electrically coupled and pads 20 which will form a portion of a digit line contact to the wafer 10. The pads are separated by a dielectric layer 22, for example borophosphosilicate glass (BPSG). Also depicted is a second layer of dielectric 24 which may be one or more layers of TEOS and/or BPSG. In this embodiment, layer 24 has a thickness of about 23,000 Å (23 KÅ). Layers 10-24 form a semiconductor wafer substrate assembly for this embodiment. This structure may be formed according to means known in the art from the description herein.

Subsequent to forming the semiconductor wafer substrate assembly, an underlayer 26, a hard mask 28, and a patterned photoresist layer 30 are formed as depicted in FIG. 1. The underlayer may be a carbon layer or a carbon-containing layer, for example a transparent carbon (TC) layer, for this embodiment about 1 KÅ and about 3 KÅ thick. Other thicknesses are contemplated, depending on the application. The formation of a transparent carbon layer of a type sufficient for practicing the present invention is known in the art. For example, US Pat. App. Pub. No. 2005/0059262A1, U.S. Ser. No. 10/661,379, which is assigned to Micron Technology, Inc. and incorporated herein by reference as if set forth in its entirety, addresses the formation of a suitable transparent amorphous carbon layer. Other suitable carbon and carbon-containing layers include boron-doped amorphous carbon (a:C—B), a spun-on carbon-containing layer such as ULX-78 available from Shin-Etsu Chemical Co., Ltd. of Tokyo, Japan. In one embodiment, the hard mask 28 may be formed from a substantially carbon-free material. For purposes of this disclosure, “substantially carbon-free” refers to a layer having less than about 0.1 atom % carbon. In another embodiment, the hard mask may comprise both carbon and another material, such as silicon, which will oxidize within a few seconds during a subsequent etch of the underlayer with an oxygen plasma, and results in an etch-resistant oxide shell. For the depicted embodiment, the hard mask may be a dielectric antireflective coating (DARC) layer between about 200 Å and about 600 Å thick, but may also be formed from silicon, silicon dioxide (SiO₂), silicon nitride (Si₃N₄), or other silicon-containing materials including polymers and multilayer resists (MLR), depending on the particular embodiment. The patterned photoresist layer 30 is formed in accordance with known techniques. A separate bottom antireflective coating (BARC, not depicted) may be disposed between the photoresist layer and the hard mask for improving resolution and/or otherwise aiding manufacturability.

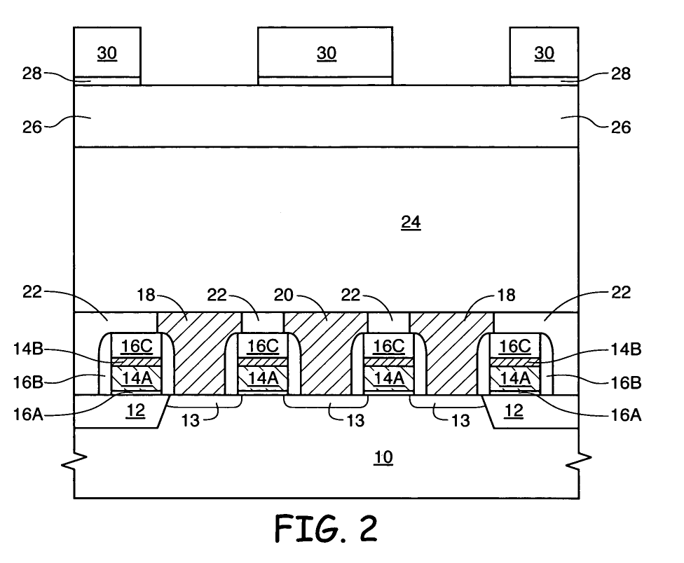

After forming the FIG. 1 structure, the photoresist layer 30 is used as a mask to etch the hard mask 28. To etch the hard mask, the FIG. 1 structure is first placed into an etch (deposition) chamber, or remains in such a chamber from a previous manufacturing act. It should be noted that the processing conditions described herein are for use with a LAM TCP9400plasma etcher, but they may be modified for performing the process of the present invention with other equipment by one of ordinary skill in the art. Within the etch chamber, the FIG. 1 structure is exposed to an etch, for example comprising tetrafluoromethane (CF₄) and helium at a flow rate of between about 10 sccm and about 100 sccm, while maintaining a chamber electrode temperature of between about 0° C. and about 70° C., a pressure of between about 10 millitorr (mT), a source power of between about 200 Watts (W) and about 600 W and a bias voltage of between about 20 volts (V) to about 350V. As this etch removes the hard mask at a rate of between about 20 Å sec and about 50 Å sec, the etch is performed for a duration of between about 10 seconds and about 30 seconds to remove the exposed hard mask portions. Subsequent to the etch of the hard mask 28, the structure of FIG. 2 remains.

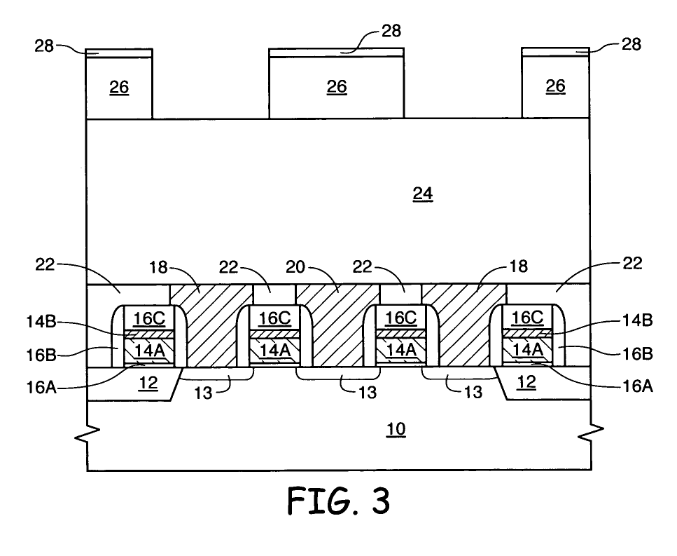

Next, the carbon or carbon-containing underlayer 26 is removed by exposing the FIG. 2 structure to an etch according to the present invention. Thus the underlayer is sacrificial, as it may be completely removed. The etch comprises the use of boron trichloride (BCl₃) and oxygen (O₂), and may further comprise one or more noble gases, for example one or more of helium and argon, and may further comprise other gases including Cl₂ and HBr to improve etch performance. In particular, BCl₃ is introduced into the chamber at a flow rate of between about 1 sccm and about 100 sccm, more preferably at a flow rate of between about 1 sccm and about 25 sccm, and most preferably at a flow rate of between about 3 sccm and about 10 sccm. Oxygen is introduced into the chamber at a flow rate of between about 10 sccm and about 500 sccm, more preferably at a flow rate of between about 10 sccm and about 150 sccm, and most preferably at a flow rate of between about 20 sccm and about 100 sccm. If used, the one or more noble gases are each introduced into the chamber at a flow rate of between about 0 sccm and about 500 sccm, more preferably at a flow rate of between about 20 sccm and about 300 sccm, and most preferably at a flow rate of between about 50 sccm and about 200 sccm. (As is known by one of ordinary skill in the art, at a flow rate of 0 sccm some gas is injected into the chamber due to the lower, subambient chamber pressure used with low pressure processes.) The noble gas, preferably used, functions to change plasma properties and neutral gas chemistry to achieve a more desirable etch result. The etch is performed at a chamber pressure of between about 1 mT and about 50 mT, and more preferably between about 1 mT and 15 mT, a chamber electrode temperature of between about −10° C. and about 85° C., and more preferably between about 20° C. and about 70° C. Source power is maintained to between about 100 W and about 1,000 W, and more preferably to between about 200 W and about 1,000 W, and bias voltage is maintained to between about 20V to about 500V, more preferably to between about 100V and about 400V, and most preferably to between about 100V and 300V. At the specified ranges, the etch removes carbon at a rate of between about 30 Å sec and about 80 Å sec, and will remove a carbon-containing nonoxidized material at a rate of between about 35 Å sec and about 90 Å sec. Thus, for the TC underlayer thickness discussed above at between about 1 KÅ thick to about 3 KÅ thick, the underlayer is exposed to the etch for between about 35 seconds and about 100 seconds. At a bias voltage of about 150V, a TC carbon underlayer, and a hard mask comprising SiO₂, the underlayer:hard mask etch ratio is expected to be between about 20:1 and about 25:1, for example around 22:1. The actual etch rate of the underlayer is determined by the process conditions and the chemical nature of the etch, and not to a large extent by the hard mask material itself. The etch rate may be outside the range listed above depending on the process conditions. It is further expected that a much higher selectivity may be achieved when the bias voltage (i.e. the ion energy) is further reduced. After the etch of the TC underlayer, the structure of FIG. 3 remains. In this embodiment, the remaining photoresist is completely removed during the etch of the underlayer. Once the photoresist is completely removed before completion of the etch, the hard mask is exposed to the etch, which begins to etch the hard mask but at a much slower rate than the etch of the underlayer. In the case where the hard mask comprises carbon and an oxidized material such as silicon, the oxidized material forms an oxide shell which protects the polymer component and thus the integrity of the hard mask.

With increasing flow rates of BCl₃ above the specified maximum of about 100 sccm, the etch rate may be reduced and an undesirable residue may begin to form. With increasing flow rates of oxygen above the specified maximum of about 500 sccm, an undercut may occur due to an increasingly isotropic etch component. The etch rate is a function of the total flow rate and the flow ratio of the BCl₃:O₂.

During the etch of the underlayer, sidewalls formed in the underlayer may be coated with a thin passivation layer, for example a polymer, which reduces or prevents lateral etching, and thus vertical or near-vertical sidewalls are formed in the underlayer. If polymer coating occurs, the passivation layer likely originates from the plasma chemistry.

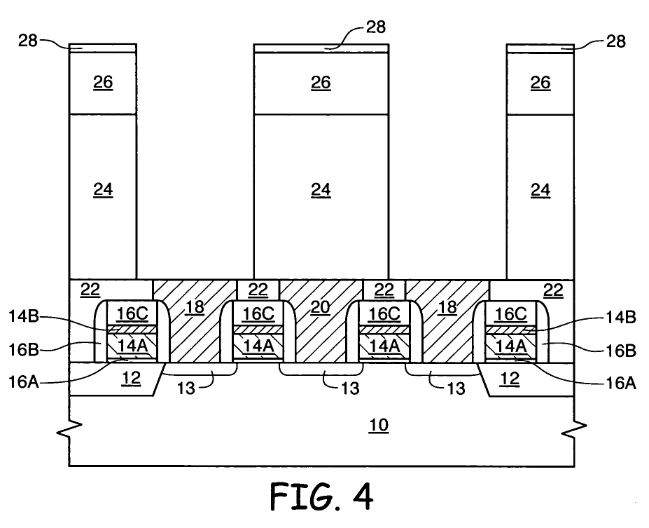

Subsequent to forming the FIG. 3 structure, the dielectric layer 24 is etched using a conventional anisotropic oxide dry etch to expose polysilicon pad 18 to result in the structure of FIG. 4.

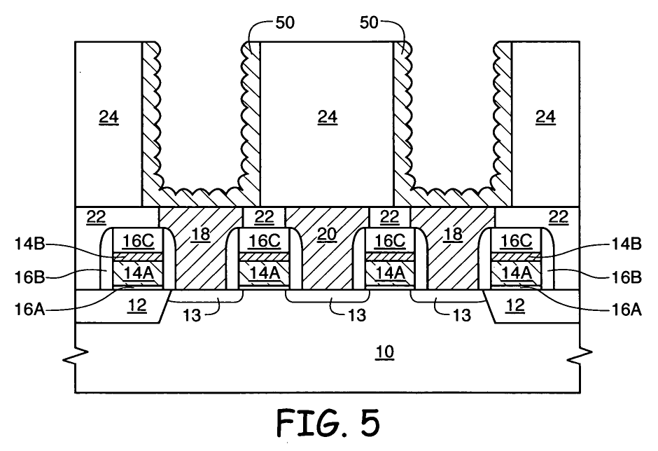

Next, the hard mask 28 and underlayer 26 are removed. A Si₃N₄ hard mask 28 may be removed during the dry etching of the silicon dioxide 22, 24 and the polysilicon 18, typically using a dry etch chemistry comprising fluorine, chlorine, and bromine. Subsequently, the carbon or carbon-containing underlayer 26 may be removed selective to the SiO₂ layers 22, 24 and polysilicon pads 18 using an oxygen plasma strip. In this embodiment, a conformal capacitor bottom plate layer is formed from hemispherical grain silicon (HSG), then horizontal portions of the bottom plate layer which overlie dielectric layer 24 are removed according to techniques known in the art. This results in the structure of FIG. 5, which depicts a pair of completed capacitor bottom plates 50 each electrically coupled to a polysilicon contact pad 18 through physical contact. Wafer processing may then continue to form a completed semiconductor device.

The embodiment of FIGS. 1-5 describe one particular use of the invention, but the underlayer may be masked and patterned using the inventive etch to form a pattern for myriad structures. Uses may include the patterning of word and bit lines, other conductive lines, conductive interconnects, other dielectric structures to form a damascene or double damascene structure, or any other various structures which requires a patterning etch.

In addition to BCl₃, it is contemplated that other compounds may function in combination with O₂ and, optionally, one or more noble gases and other gases. For example, the BCl₃ may be replaced with tribromoborane (BBr₃) using the same flows described above for BCl₃.

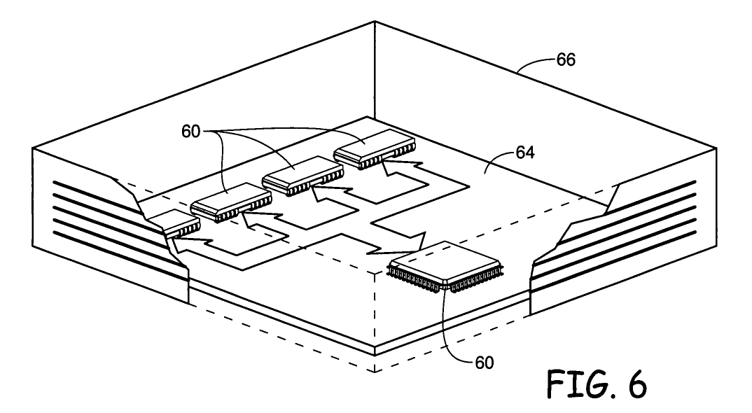

As depicted in FIG. 6, a semiconductor device 60 formed in accordance with the invention may be attached along with other devices such as a microprocessor 62 to a printed circuit board 64, for example to a computer motherboard or as a part of a memory module used in a personal computer, a minicomputer, or a mainframe 66. FIG. 6 may also represent use of device 60 in other electronic devices comprising a housing 66, for example devices comprising a microprocessor 62, related to telecommunications, the automobile industry, semiconductor test and manufacturing equipment, consumer electronics, or virtually any piece of consumer or industrial electronic equipment.

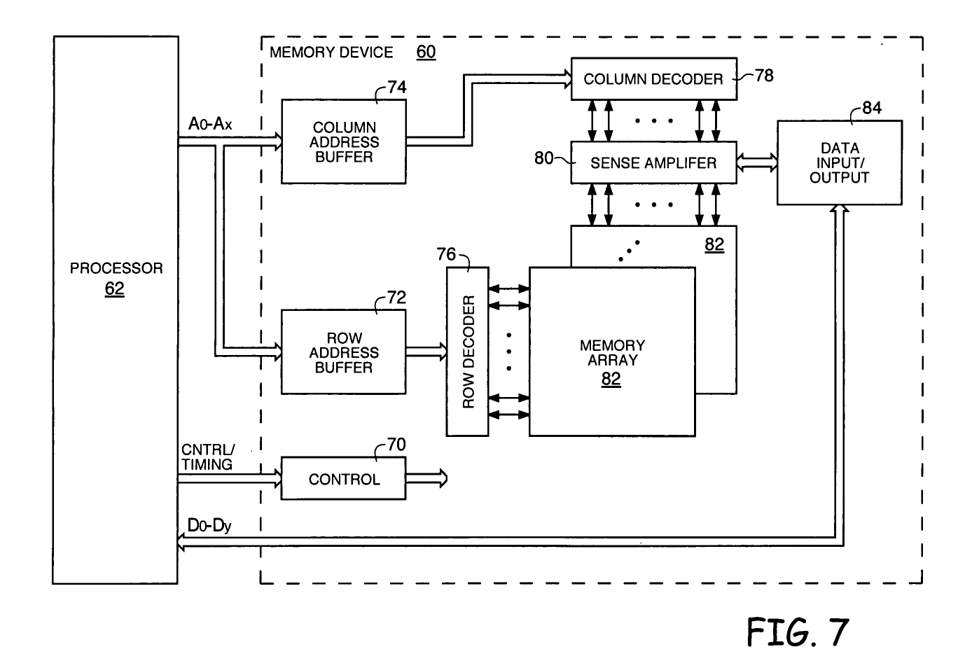

The process and structure described herein may be used to manufacture a number of different structures comprising a patterned layer formed according to the inventive process using a patterned masking layer etched using the inventive etch. FIG. 7, for example, is a simplified block diagram of a memory device such as a dynamic random access memory having container capacitors, word lines, bit lines, and/or other features which may be formed using an embodiment of the present invention. The general process used to operate such a device is known to one skilled in the art. FIG. 7 depicts a processor 62 coupled to a memory device 60, and further depicts the following basic sections of a memory integrated circuit: control circuitry 70; row 72 and column 74 address buffers; row 76 and column 78 decoders; sense amplifiers 80; memory array 82; and data input/output 84.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. It is therefore contemplated that the appended claims will cover any such modifications or embodiments as fall within the true scope of the invention.

1. A method for use during manufacture of a semiconductor device, comprising:
providing a layer;
forming a carbon-containing underlayer over the layer;
forming a patterned hard mask over the underlayer;
exposing the carbon-containing underlayer and the patterned hard mask to an etchant comprising both oxygen and a gas selected from the group consisting of boron trichloride (BCl₃) and tribromoborane (BBr₃) to etch the carbon-containing underlayer using the patterned hard mask as a pattern; and
etching the layer using the etched carbon-containing underlayer as a pattern.

2. The method of claim 1 further comprising selecting the hard mask to comprise carbon and an oxide.

3. The method of claim 1 further comprising selecting the hard mask to comprise carbon and silicon dioxide.

4. The method of claim 1 further comprising selecting the hard mask to be substantially carbon-free.

5. The method of claim 1 further comprising:
providing a semiconductor wafer substrate assembly including the layer, the carbon-containing underlayer and the patterned hard mask;
placing the semiconductor wafer substrate assembly into an etch chamber;
during the exposure of the carbon-containing underlayer to the etchant:
introducing the material selected from the group consisting of BCl₃ and BBr₃ into the chamber at a flow rate of between about 1 sccm and about 100 sccm into the chamber; and
introducing the oxygen into the chamber at a flow rate of between about 10 sccm and about 500 sccm.

6. The method of claim 5 further comprising introducing at least one noble gas into the chamber at a flow rate of between about 0 sccm and about 500 sccm.

7. The method of claim 5 further comprising, during the exposure of the underlayer to the etchant:
maintaining pressure within the chamber to between about 1 mT and about 50 mT;
maintaining a chamber electrode temperature of between about −10° C. and about 85° C.;
maintaining source power to between about 100 W and about 1,000 W; and
maintaining a bias voltage to between about 20V and about 500V.

8. The method of claim 1 further comprising, during the exposure of the underlayer to the etchant:
introducing the material selected from the group consisting of BCl₃ and BBr₃ into the chamber at a flow rate of between about 3 sccm and about 10 sccm into the chamber; and
introducing the oxygen into the chamber at a flow rate of between about 20 sccm and about 100 sccm.
maintaining pressure within the chamber to between about 1 mT and about 15 mT;
maintaining a chamber electrode temperature of between about 20° C. and about 70° C.;
maintaining source power to between about 200 W and about 1,000 W; and
maintaining a bias voltage to between about 100V and about 300V.

9. The method of claim 1 further comprising:
forming an unpatterned hard mask over the carbon-containing underlayer;
forming a patterned photoresist layer over the hard mask; and
etching the unpatterned hard mask using the patterned photoresist layer as a pattern to form the patterned hard mask.

10. The method of claim 9 further comprising:
forming a bottom antireflective coating (BARC) on the carbon-containing underlayer; and
forming the patterned photoresist layer on the BARC.

11. A method for use in forming a semiconductor device feature, comprising:
providing a semiconductor wafer substrate assembly comprising a layer;
forming a carbon-containing underlayer over the layer;
forming a patterned hard mask comprising a material selected from the group consisting of a substantially carbon-free layer and an oxidizable material over the underlayer;
placing the semiconductor wafer substrate assembly into an etch chamber;
in the etch chamber, exposing the carbon-containing underlayer and the patterned hard mask to an etchant comprising both oxygen at a flow rate of between about 10 sccm and about 50 sccm and a gas selected from the group consisting of boron trichloride (BCl₃) and tribromoborane (BBr₃) at a flow rate of between about 1 sccm and about 100 sccm to etch the carbon-containing underlayer using the patterned hard mask as a pattern; and
etching the layer using the etched carbon-containing underlayer as a pattern.

12. The method of claim 11 wherein the layer is a dielectric layer and the method further comprises:
during the etch of the layer, forming a recess in the dielectric layer; and
forming a conductive layer within the recess in the dielectric layer.

13. The method of claim 11 further comprising selecting the hard mask to comprise silicon.

14. The method of claim 11 further comprising introducing at least one noble gas into the chamber at a flow rate of between about 0 sccm and about 500 sccm.

15. The method of claim 11 further comprising, during the exposure of the underlayer to the etchant:
maintaining pressure within the chamber to between about 1 mT and about 50 mT;
maintaining a chamber electrode temperature of between about −10° C. and about 85° C.;
maintaining source power to between about 100 W and about 1,000 W; and
maintaining a bias voltage to between about 20V and about 500V.

16. The method of claim 11 further comprising, during the exposure of the underlayer to the etchant:
introducing the material selected from the group consisting of BCl₃ and BBr₃ into the chamber at a flow rate of between about 3 sccm and about 10 sccm into the chamber;
introducing the oxygen into the chamber at a flow rate of between about 20 sccm and about 100 sccm;
maintaining pressure within the chamber to between about 1 mT and about 15 mT;
maintaining a chamber electrode temperature of between about 20° C. and about 70° C.; and
maintaining source power to between about 200 W and about 1,000 W.

17. The method of claim 11 further comprising;
forming a blanket hard mask layer on the underlayer;
forming a bottom antireflective coating (BARC) on the hard mask layer;
forming a patterned photoresist layer on the BARC;
patterning the BARC using the patterned photoresist layer as a pattern; and
patterning the blanket hard mask layer using the patterned photoresist layer as a pattern to form the patterned hard mask.

18. A method for use during manufacture of an electronic system, comprising:
providing a semiconductor device formed by a method comprising:
providing a layer;
forming a carbon-containing underlayer over the layer;
forming a hard mask over the carbon-containing underlayer;
forming a patterned layer over the hard mask;
etching the hard mask using the patterned layer as a pattern;
exposing the carbon-containing underlayer and the etched hard mask to an etchant comprising both oxygen and a gas selected from the group consisting of boron trichloride (BCl₃) and tribromoborane (BBr₃) to etch the carbon-containing underlayer using the etched hard mask as a pattern; and
etching the layer using the etched carbon-containing underlayer as a pattern;
providing a microprocessor; and
electrically coupling the semiconductor device to the microprocessor to facilitate the passage of electrical signals from the microprocessor to the semiconductor device.

19. The method of claim 18, further comprising selecting the hard mask to comprise carbon and an oxide.

20. The method of claim 18, further comprising selecting the hard mask to comprise carbon and silicon dioxide.

21. The method of claim 18, further comprising selecting the hard mask to be substantially carbon-free.

22. The method of claim 18 further comprising:
providing a semiconductor wafer substrate assembly including the layer, the carbon-containing underlayer and the patterned hard mask;
placing the semiconductor wafer substrate assembly into an etch chamber;
during the exposure of the carbon-containing underlayer to the etchant:
introducing the material selected from the group consisting of BCl₃ and BBr₃ into the chamber at a flow rate of between about 1 sccm and about 100 sccm into the chamber; and
introducing the oxygen into the chamber at a flow rate of between about 10 sccm and about 500 sccm.

23. The method of claim 18 further comprising;
forming a bottom antireflective coating (BARC) on the hard mask; and
forming the patterned layer on the BARC.

24-27. (canceled)
